(19) United States
(12) Patent Application Publication
(10) Pub. No.: US 2026/0162697 A1
(43) Pub. Date: Jun. 11, 2026

(54) MEMORY UNDER-VOLTAGE MITIGATION

(71) Applicant: QUALCOMM Incorporated, San Diego, CA (US)

(72) Inventors: Hoan Huu NGUYEN, Cary, NC (US); Nitin MAKHIJA, San Jose, CA (US); Prit Ketan GALA, San Jose, CA (US)

(21) Appl. No.: 18/970,545

(22) Filed: Dec. 5, 2024

(51) Int. Cl. G11C 5/14

(52) U.S. Cl. CPC G11C 5/147

(57) ABSTRACT

Certain aspects of the present disclosure provide techniques for mitigating memory under-volt scenarios. According to certain aspects, dynamic voltage and frequency scaling (DVFS) logic may be used to decide on optimal points to switch the memory supply voltages from CPU_Mx to CPU_Cx (or vice versa), to eliminate or mitigate memory under-voltage issues.

### FIELD OF THE DISCLOSURE

Aspects of the present disclosure relate to techniques for mitigating memory under-volt scenarios.

### BACKGROUND

A CPU may include a processing unit (e.g., a core) that includes local memory, such as level 1 cache. The local memory may include a memory array that includes a plurality of memory cells. For instance, the memory cells may include static random access memory (SRAM) cells.

CPU clusters (CCs) may use different types of memory with different types of bitcells. For example, core memory (e.g., local memory accessed by a single core) may use a high current (HC) bitcell design to support high performance applications. A last level cache (LLC) shared by multiple cores, on the other hand, may use a high density (HD) bitcell design for area optimization (due to potentially large LLC size). LLC typically refers to a highest-numbered cache that is accessed by the cores prior to fetching from memory.

### SUMMARY

One aspect provides a method. The method includes selecting a performance state (p-state) that defines a frequency and voltage at which at least one processor operates; and using dynamic voltage and frequency scaling (DVFS) logic to select a first voltage supply or a second voltage supply to couple to a first memory of a first type, based on the selected p-state.

Other aspects provide: an apparatus operable, configured, or otherwise adapted to perform any one or more of the aforementioned methods and/or those described elsewhere herein; a non-transitory, computer-readable media comprising instructions that, when executed (e.g., directly, indirectly, after pre-processing, without pre-processing) by one or more processors of an apparatus, cause the apparatus to perform the aforementioned methods as well as those described elsewhere herein; a computer program product embodied on a computer-readable storage medium comprising code for performing the aforementioned methods as well as those described elsewhere herein; and/or an apparatus comprising means for performing the aforementioned methods as well as those described elsewhere herein. By way of example, an apparatus may comprise a processing system, a device with a processing system, or processing systems cooperating over one or more networks.

The following description and the appended figures set forth certain features for purposes of illustration.

### BRIEF DESCRIPTION OF DRAWINGS

The appended figures depict certain features of the various aspects described herein and are not to be considered limiting of the scope of this disclosure.

FIG. 1 depicts an example system-on-chip (SoC).

FIG. 2 depicts an example application of an adaptive power multiplexer (APM) used to connect different power rails to a memory.

FIGS. 3A and 3B depict the APM of FIG. 2 in different states.

FIG. 4 depicts a timing diagram illustrating a transition of a voltage rail that may result in a switch of the APM from a first state to a second state.

FIG. 5 depicts a timing diagram illustrating a transition of a voltage rail that may result in a switch of the APM from a second state to a first state.

FIG. 6 depicts a timing diagram illustrating an ideal voltage comparison based switching scenario that may avoid an under-voltage condition.

FIG. 7 depicts a timing diagram illustrating a non-ideal voltage comparison based switching scenario that may result in an under-voltage condition.

FIG. 8 depicts a timing diagram illustrating another non-ideal voltage comparison based switching scenario.

FIGS. 9A and 9B depict example dynamic voltage and frequency scaling (DVFS) entries without and with an APM, respectively.

FIGS. 10A and 10B depict example dynamic voltage and frequency scaling (DVFS) entries designed to trigger an APM mux, in accordance with aspects of the present disclosure.

FIG. 11 depicts a timing diagram illustrating logic that supports DVFS based switching, in accordance with aspects of the present disclosure.

FIG. 12 depicts a timing diagram illustrating an example of DVFS based voltage switching, in accordance with aspects of the present disclosure.

FIG. 13 depicts a timing diagram illustrating an example of DVFS based voltage switching, in accordance with aspects of the present disclosure.

FIG. 14 depicts an example method in accordance with aspects of the present disclosure.

FIG. 15 depicts an example device in accordance with aspects of the present disclosure.

### DETAILED DESCRIPTION

Aspects of the present disclosure relate to techniques for mitigating memory under-volt scenarios.

As noted above, different types of memory may use different types of bitcells. For example, core memory an HC bitcell design for high performance while an LLC may use an HD bitcell design for area optimization.

In certain implementations, HC and HD memories may share a common power rail applied to their voltage input Vddmx (e.g., CPU_Mx, which is typically always on at a certain voltage level). While this approach may be efficient, it may also result in tradeoffs that are less than ideal. For example, the HD bitcell voltage may need to be kept at or below a maximum voltage, Vmax (e.g., 1.05v). Unfortunately, constraining the voltage of HC memory in this manner may result in performance degradation.

In some cases, to remove this constraint and achieve better performance and allow HC memories to operate at a higher maximum supply voltage, an adaptive power multiplexer (APM) may be used to connect different power rails to HC memory. For example, in a high performance state (p-state), the APM may connect the HC memory to a different voltage rail (CPU_Cx) whose level may be dynamically changed to a higher voltage (to support a higher clock frequency). The APM may be used to connect the HC memory to CPU_Cx, when CPU_Cx exceeds CPU_Mx. On the other hand, when CPU_Mx exceeds CPU_Cx, the APM may connect the HC memory to CPU_Mx.

The APM typically employs a voltage comparator to detect the voltage difference between CPU_Cx and CPU_Mx and the APM controller then switches memories supply voltage as described above. Unfortunately, non-ideal factors, such as analog voltage comparator input offset noise, comparator latency, APM controller latency, and physical distribution delay, may lead to an undesired scenario where the memories supply voltage is much lower than expected and operation of the memory may be undefined.

Aspects of the present disclosure propose solutions that may utilize dynamic voltage and frequency scaling (DVFS) logic to decide on optimal points to switch the memory supply voltages from CPU_Mx to CPU_Cx (or vice versa), to eliminate the under-voltage issue described above. As will be described in greater detail below, the mechanisms may be integrated in the DVFS control logic. In addition to increasing performance and eliminating under-voltage issues, the proposed techniques may also eliminate the need for analog voltage comparators, which may save power and area.

### Introduction to System-on-Chip (SoC)

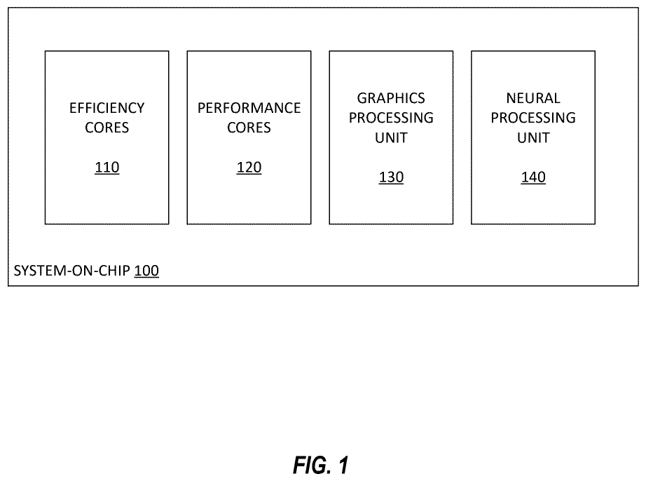

FIG. 1 illustrates an example system-on-chip (SoC) 100 with different types of IP cores on which artificial intelligence workloads can be processed, according to aspects of the present disclosure.

As illustrated, the SoC 100 includes one or more efficiency cores 110, one or more performance cores 120, a graphics processing unit (GPU) 130, and a neural processing unit (NPU) 140, amongst other processing units and components (not illustrated) on which various compute workloads can be processed (e.g., tensor processing units, application-specific integrated circuits (ASICs), digital signal processors (DSPs), and the like). The efficiency cores 110 and the performance cores 120, in some aspects, may be processors implementing a same processing architecture (e.g., processors implementing the ARM or RISC-V architectures). Generally, the efficiency cores 110 may have lower performance (e.g., as measured by a number of operations per second that the efficiency cores 110 can perform) than the performance cores 120, but may use less power than the performance cores 120 in executing a workload. The SoC 100 may include any number of efficiency cores 110 and any number of performance cores 120. The GPU 130 may be a specialized processing unit which is configured to perform large mathematical operations (e.g., matrix, vector, tensor, etc. operations) in parallel.

The NPU 140, is generally a specialized circuit configured for implementing control and arithmetic logic for executing machine learning algorithms, such as algorithms for processing artificial neural networks (ANNs), deep neural networks (DNNs), random forests (RFs), and the like. An NPU may sometimes alternatively be referred to as a neural signal processor (NSP), tensor processing unit (TPU), neural network processor (NNP), intelligence processing unit (IPU), vision processing unit (VPU), or graph processing unit.

The NPU 140 may be configured to accelerate the performance of common machine learning tasks, such as image classification, machine translation, object detection, and various other predictive models. In some examples, a plurality of NPUs may be instantiated on a single chip, such as a system on a chip (SoC), while in other examples such NPUs may be part of a dedicated neural-network accelerator.

NPUs, such as the NPU 140, may be optimized for training or inference, or in some cases configured to balance performance between both. For NPUs that are capable of performing both training and inference, the two tasks may still generally be performed independently.

NPUs designed to accelerate training are generally configured to accelerate the optimization of new models, which is a highly compute-intensive operation that involves inputting an existing dataset (often labeled or tagged), iterating over the dataset, and then adjusting model parameters, such as weights and biases, in order to improve model performance. Generally, optimizing based on a wrong prediction involves propagating back through the layers of the model and determining gradients to reduce the prediction error.

NPUs designed to accelerate inference are generally configured to operate on complete models. Such NPUs may thus be configured to input a new piece of data and rapidly process this new piece through an already trained model to generate a model output (e.g., an inference).

Each of the processing units on the SoC 100 (e.g., the efficiency cores 110, the performance cores 120, the GPU 130, the NPU 140, and/or other processing units not illustrated in FIG. 1) generally have different performance characteristics. These performance characteristics may include power slope, leakage power, dynamic clock and voltage scaling points (e.g., points at which processing core clock speed and voltage draw scales upward or downward), instructions-per-clock cycle (IPC) performance levels, and the like.

Workloads executing on the SoC 100 may also be defined by various characteristics which may influence how these workloads, or portions thereof, are scheduled for execution on various processing units of the SoC 100. For example, the workloads may be characterized by a number of stages (e.g., layers) in an artificial intelligence model executing on the SoC 100, a length of an input into the artificial intelligence model, data types associated with each stage or layer of the artificial intelligence model.

### Aspects Related to Memory Under-Voltage Mitigation

Aspects of the present disclosure relate to techniques for mitigating memory under-voltage scenarios.

Under-voltage generally refers to a scenario where a memory is supplied a lower voltage than it is designed to operate with. Memory is typically designed to operate at certain voltage and frequency. If the voltage supplied is lower than it is designed for (e.g., 100 mv below), the memory may not be functional.

CPU clusters (CCs) that include different types of processing cores (e.g., such as those shown in FIG. 1) may utilize memory with different types of bitcells. As noted above, in some cases, to achieve better performance and allow HC memories to operate at a higher maximum supply voltage, an adaptive power multiplexer (APM) may be used to connect different power rails to HC memory.

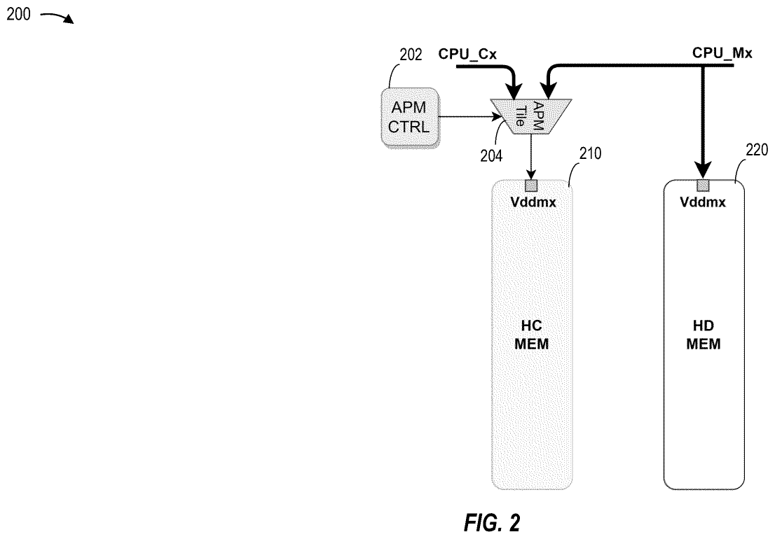

As illustrated in diagram 200 of FIG. 2, an SoC may use an APM 202 for managing SOC power modes. The APM may include an APM controller 202 to send control signals to other modules, such as an APM multiplexor 204. In this manner, an APM can help subsystems (and different types of memory) operate independently in sleep and active modes, which can help avoid wasting power.

The SoC may also include a plurality of sections, each with a separate dc power (voltage supply) rail. For example, the SoC may include a first section (e.g., an Mx section) with a first power rail set to a first voltage level (e.g., CPU_Mx). The SOC may also include a second section, for example, with a transient (changing) voltage level (e.g., a Cx section), which may be turned ON and OFF, with a second power rail with a transient voltage level (e.g. CPU_Cx).

As illustrated, CPU_Mx may be connected to the supply voltage input (Vddmx) of HD memory 220. The APM controller 202 may control APM multiplexor 204 to connect either CPU_Mx or CPU_Cx to the supply voltage input of HC memory 210, allowing a higher voltage and increased performance in certain scenarios.

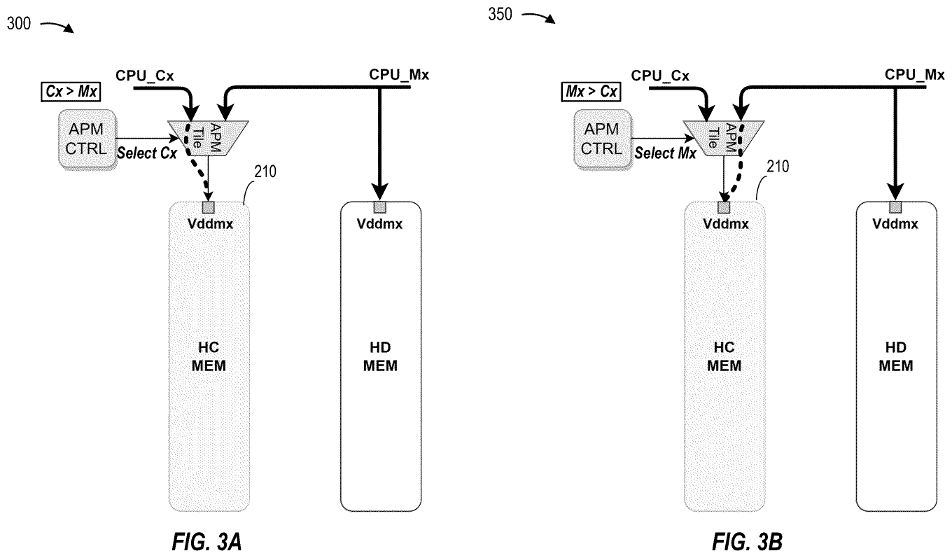

For example, as illustrated in diagram 300 of FIG. 3A, the APM may select CPU_Cx to allow HC memory 210 to operate at a higher maximum supply voltage, in a high performance state (p-state), to support a higher clock frequency. In some cases, the APM controller may utilize an analog voltage comparator that controls the APM multiplexor to select CPU_Cx when CPU_Cx exceeds CPU_Mx.

On the other hand, as illustrated in diagram 350 of FIG. 3B, the APM may select CPU_Mx, for example, in a lower p-state where HC memory 210 can operate at a lower clock frequency. As indicated, the analog voltage comparator that controls the APM multiplexor may select CPU_Cx when CPU_Mx exceeds CPU_Cx.

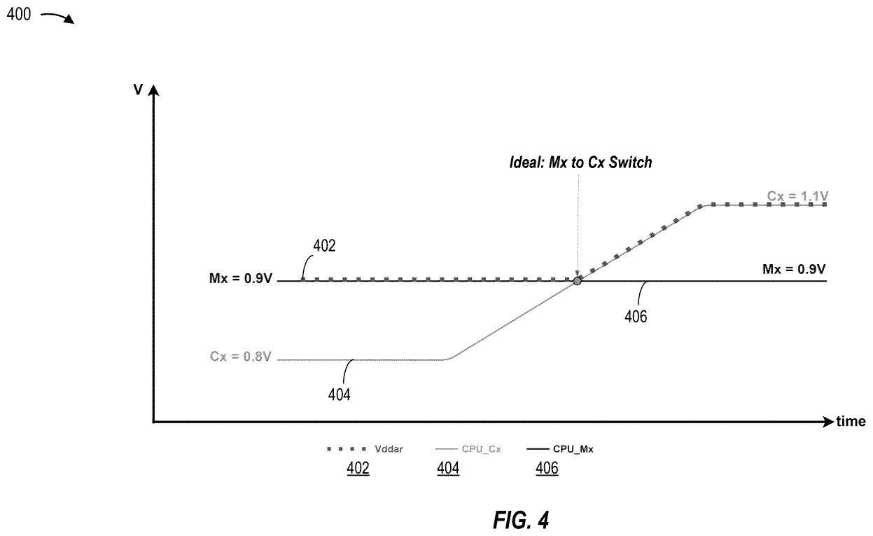

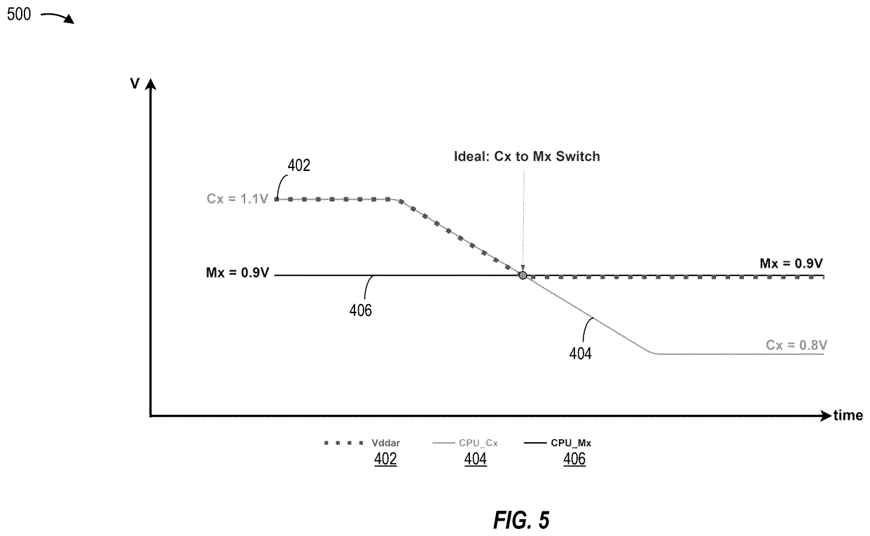

FIGS. 4 and 5 illustrate example scenarios for switching from CPU_Cx to CPU_Mx and from CPU_Mx to CPU_Cx, respectively, assuming ideal switching conditions.

In diagram 400 of FIG. 4, CPU_Mx 406 is initially greater than CPU_Cx 404. Thus, the input voltage Vddar 402 output from the APM multiplexor is initially at the same voltage level as CPU_Mx. As CPU_Cx 404 increases above CPU_Mx, however the multiplexor switches and Vddar 402 is switched to CPU_Cx.

Conversely, in diagram 500 of FIG. 5, CPU_Cx 404 is initially greater than CPU_Mx 406. Thus, the input voltage Vddar 402 output from the APM multiplexor is initially at the same voltage level as CPU_Cx. As CPU_Cx 404 decreases below CPU_Mx, however the multiplexor switches and Vddar 402 is switched to CPU_Mx.

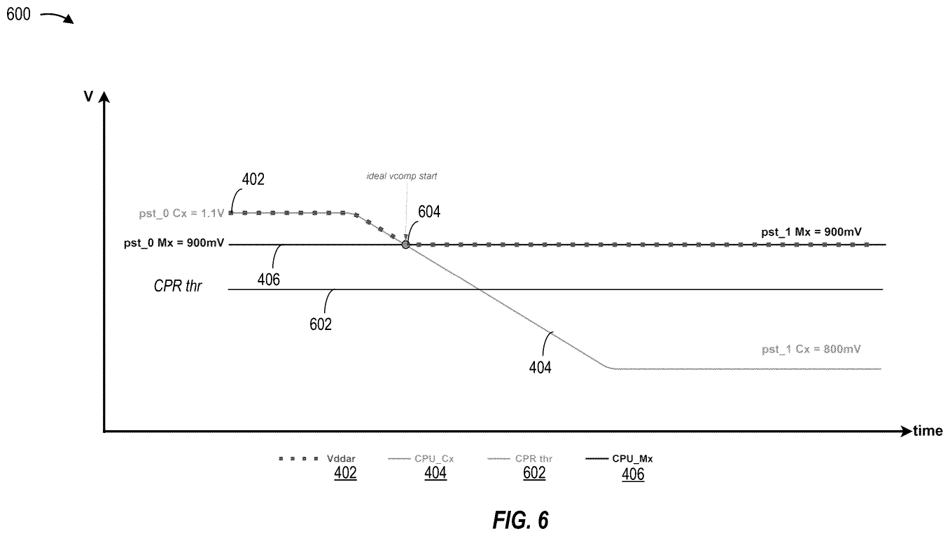

The APM circuitry may be designed to ensure that the supply voltage of the HC memory is maintained in an operational level as CPU_Cx voltage is varied. For example, as illustrated in diagram 600 of FIG. 6, ideally, the APM will switch (ideally, at point 604) from CPU_Cx to CPU_Mx before CPU_Cx falls below a core power reduction (CPR) voltage threshold 602. This may help ensure HC memory continues to operate in a defined manner.

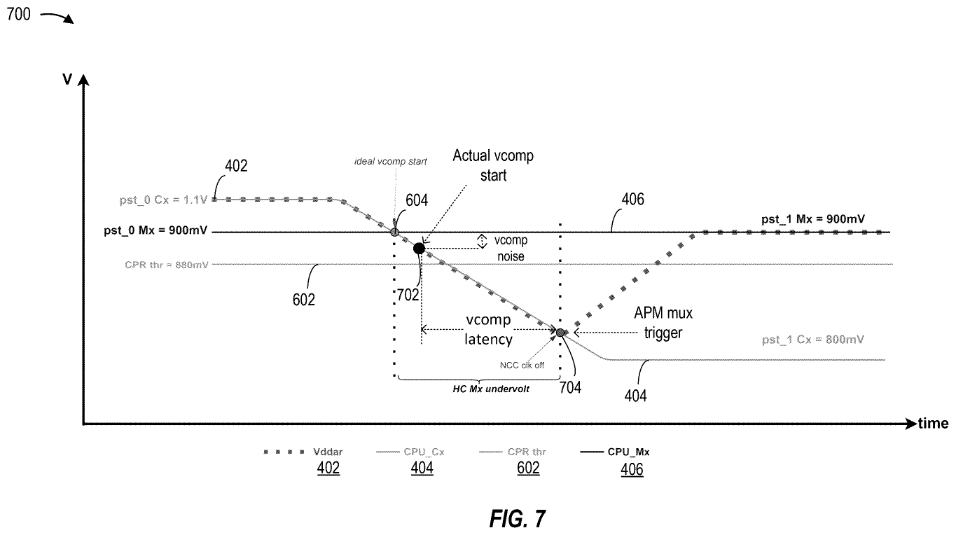

As noted above, however, as illustrated in diagram 700 of FIG. 7, various non-ideal factors may delay the switching and allow the HC memory to reach an under-voltage scenario when switching from CPU_Cx to CPU_Mx (e.g., from a high p-state to a lower p-state). As illustrated, due to voltage comparator input offset noise, the actual start of the voltage comparison switching (at 702) may be delayed relative to the ideal start (at 604). Further, voltage comparator latency may also delay when the output switches and the APM mux is triggered (at 704). APM controller latency and physical distribution delay may further contribute to the undesired scenario where the memories supply voltage is much lower than expected and operation of the memory may be undefined.

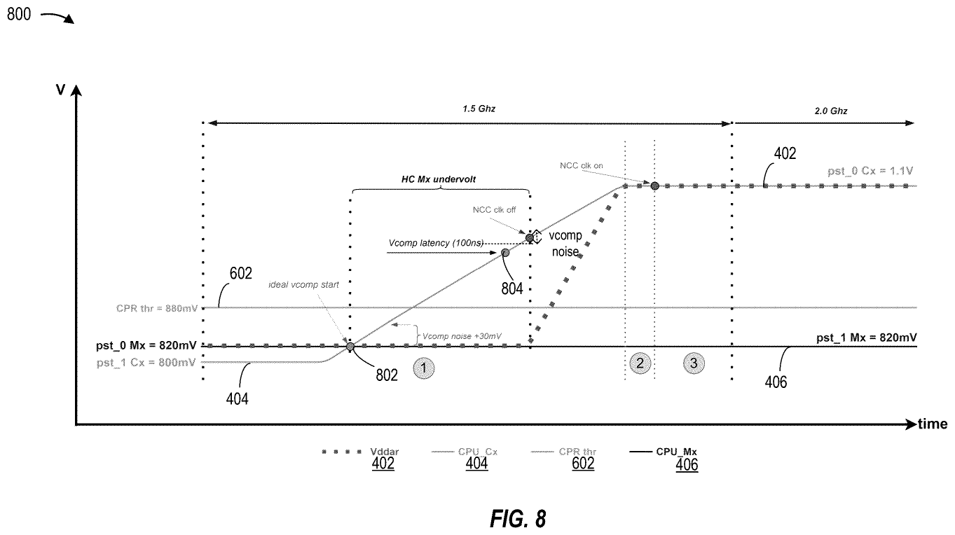

As illustrated in diagram 800 of FIG. 8, non-ideal factors may also delay the switching from CPU_Mx to CPU_Cx (e.g., from a low p-state to a higher p-state). As illustrated, due to voltage comparator input offset noise, the actual start of the voltage comparison switching (at 804) may be delayed relative to the ideal start. Further, voltage comparator latency may also delay when the output switches and the APM mux is triggered (at 804). APM controller latency and physical distribution delay may further contribute to the undesired scenario where the memories supply voltage is much lower than expected (e.g., for a corresponding frequency of the higher p-state) and operation of the memory may be undefined. The illustrated example assumes a clock frequency of 1.5 GHz in the initial (lower) p-state and a clock frequency of 2.0 GHz after the switch to the higher p-state. As indicated, the clock may be turned off for a portion of the switching between voltages.

Aspects of the present disclosure propose solutions that may utilize dynamic voltage and frequency scaling (DVFS) logic to decide on optimal points to switch the memory supply voltages from CPU_Mx to CPU_Cx (or vice versa), to eliminate the under-voltage issue described above. As will be described in greater detail below, the mechanisms may be integrated in the DVFS control logic. In addition to increasing performance and eliminating under-voltage issues, the proposed techniques may also eliminate the need for analog voltage comparators, which may save power and area.

DVFS may allow processor cores to switch between voltage and frequency levels based on real-time workload demands, automatically adjusting performance and power consumption. As an example, a processor or memory could have DVFS table entries with different voltage levels and corresponding frequencies. In some cases, each DVFS entry may correspond to a performance state (p-state). In general, higher p-states will have higher frequencies and correspondingly to higher voltages, while lower p-states will have lower frequencies and corresponding lower voltages to save power. The number of frequency steps in a DVFS table can vary depending on the processor architecture, with some offering finer-grained control than others. In some cases, an operating system may monitor system load and make decisions about when to switch between frequency levels (e.g., change p-states).

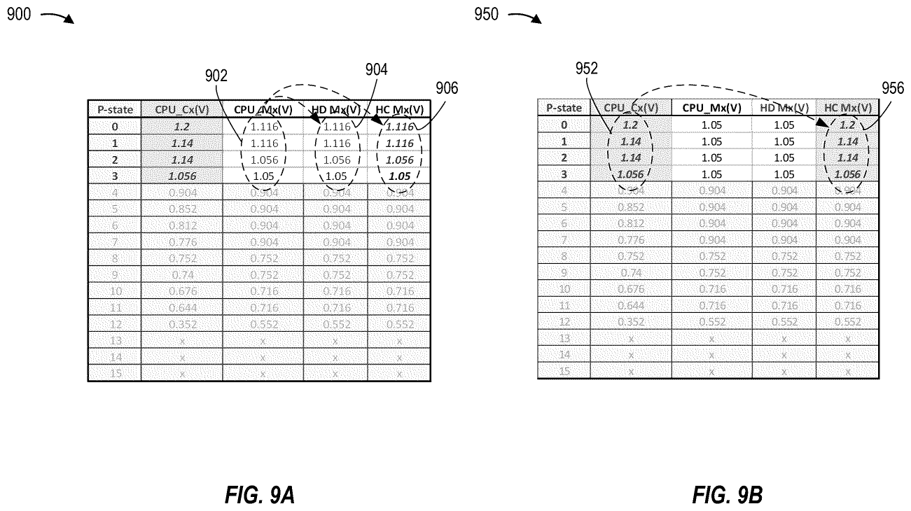

FIG. 9A illustrates an example DVFS table 900 with certain voltage levels for CPU_Cx, CPU_Mx for various p-states (the corresponding frequencies are not shown). The example illustrated in FIG. 9 may assume now APM functionality. Thus, as shown, the supply voltages (Vddmx) for both HD memory (904) and HC memory (906) may be equal to CPU_Mx (902) for all p-states.

As illustrated in table 950 of FIG. 9B, however, with APM functionality, the supply voltage of HC memory (956) may be set to CPU_Cx (952) for p-states when CPU_Cx is greater than CPU_Mx. On the other hand, the supply voltage of HC memory may be set to CPU_Mx for p-states when CPU_Cx is less than CPU_Mx.

As described above with reference to FIGS. 7 and 8, however, conventional voltage comparator based APM switching may result in under-voltage scenarios. Aspects of the present disclosure propose solutions that may utilize DVFS logic to decide on optimal points to switch the memory supply voltages from CPU_Mx to CPU_Cx (or vice versa), to eliminate the under-voltage issue described above.

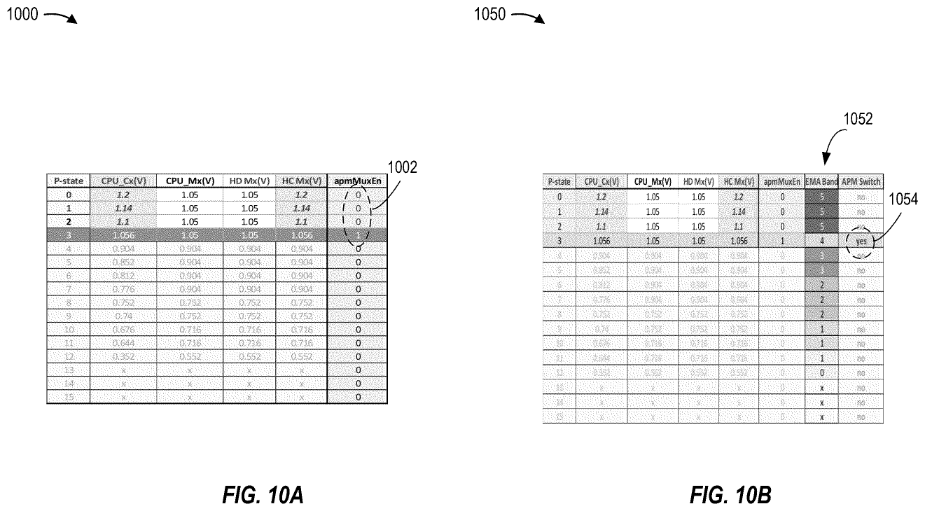

For example, FIG. 10A illustrates an example DVFS table 1000 with entries that can trigger an APM multiplexor switch via a programmable bit 1002. Labeled APM multiplexor enable (apmMuxEn), the value of this bit may be set per p-state, programmable via software.

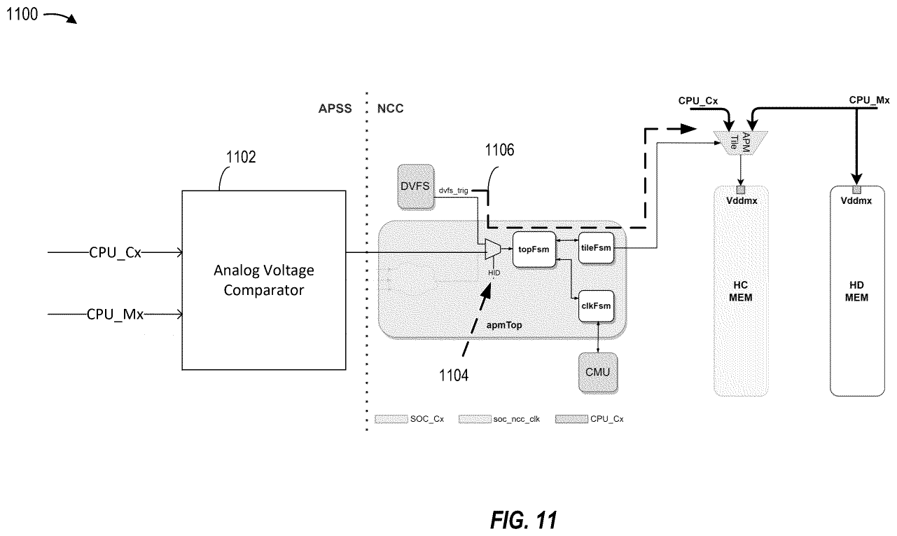

As illustrated at 1104 in FIG. 11, in some cases this bit may be used to control another multiplexor to bypass the analog voltage comparator 1102 and allow DVFS logic to trigger a voltage switch (between CPU_Cx and CPU_Mx) as indicated at 1106. Bypassing the analog voltage comparator in this manner may help avoid the under voltage scenarios described above. In some cases, the analog voltage comparator may be bypassed by DVFS logic selectively (e.g., on transition between certain p-states). In other cases, the DVFS logic may always control the voltage switching and the analog voltage comparator 1102 may be eliminated, saving area and power.

In some cases, the value of the apmMuxEn bit 1002 (or another bit) may be used to indicate which rail (CPU_Cx or CPU_Mx) that HC memory supply voltage (HC Mx) should be set to for each p-state. As indicated at 1054 in table 1050 of FIG. 10B, in some cases the bit value of apmMuxEn changing values (e.g., crossing from 0→1 or 1→0) may trigger the APM multiplexor.

FIG. 10B also illustrates how subsets of p-states may be grouped into electrical margin adjust (EMA) bands 1052. EMA bands may allow designers greater flexibility in voltage and frequency settings, allowing certain circuits to remain operational at lower voltage ranges. EMA bands may allow incremental changes in overlapping (extended) voltage ranges, when switching between widely disparate p-states (e.g., from p-state 15 to p-state 0).

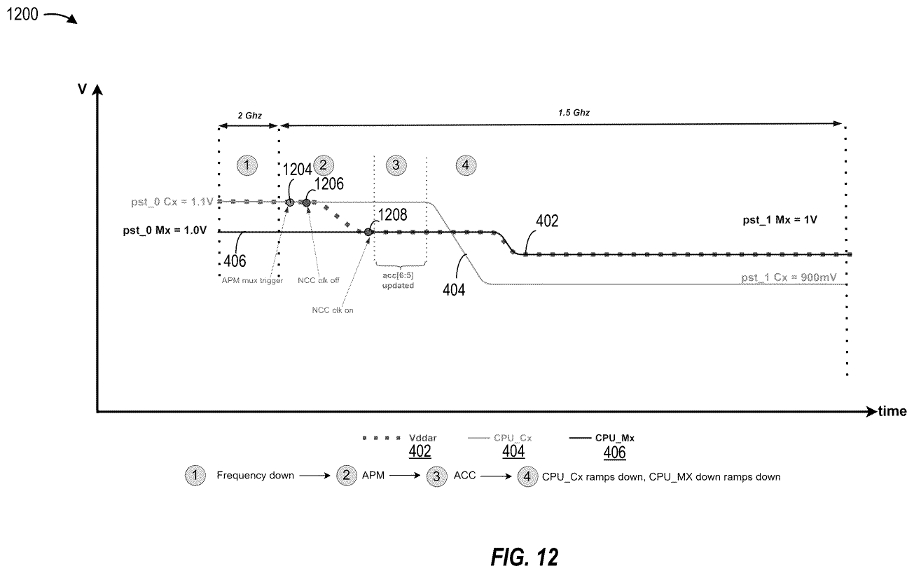

FIG. 12 illustrates an example diagram 1200 of DVFS based switching from a higher performance p-state to a lower performance p-state, in accordance with aspects of the present disclosure.

As illustrated in an initial state (1), Vddar 402 is set to CPU_Cx 404 and the clock is operating at 2.0 GHz. The APM multiplexor is triggered by DVFS logic, at 1204. As illustrated, in this state (2), the clock may be turned off (at 1206) as Vddar transitions from CPU_Cx 404 to CPU_Mx 406. Once Vddar reaches CPU_Mx, the clock is turned back on (at 1208) at 1.5 GHz. In this third state (3), CPU_Cx 404 may be brought down, reaching a final state (4) after CPU_Cx reaches its final point (e.g., 900 mv). Thus, by eliminating the latency associated with the analog voltage comparison, the DVFS based switching avoids the under-voltage exhibited in FIG. 7.

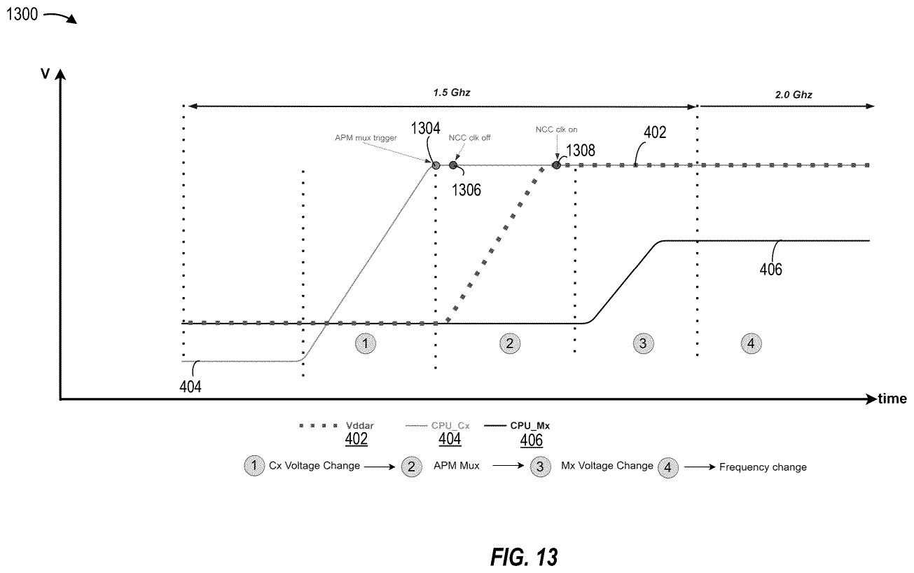

FIG. 13 illustrates an example diagram 1300 of DVFS based switching from a lower performance p-state to a higher performance p-state, in accordance with aspects of the present disclosure.

As illustrated in an initial state (1), Vddar 402 is set to CPU_Mx 406, as CPU_Cx 404 is increased. The APM multiplexor is triggered by DVFS logic, at 1304. As illustrated, in this state (2), the clock may be turned off (at 1306) as Vddar transitions from CPU_Mx 406 to CPU_Cx 404. Once Vddar reaches CPU_Cx, the clock is turned back on (at 1308). In this example, in this third state (3), CPU_Mx 406 may be brought up, reaching a final state (4) after CPU_Mx reaches its final point at which point its clock may be increased from 1.5 GHz to 2.0 GHz. Thus, by eliminating the latency associated with the analog voltage comparison, the DVFS based switching avoids the under-voltage exhibited in FIG. 8.

By utilizing DVFS logic to decide on optimal points to switch the memory supply voltages, aspects of the present disclosure may help avoid (or at least mitigate) memory under-voltage issues described above. As a result, operating voltages and frequencies of different types of memories (or other circuits) may be flexibly controlled to achieve improved performance and/or reduced power consumption, depending on current needs.

### Example Operations

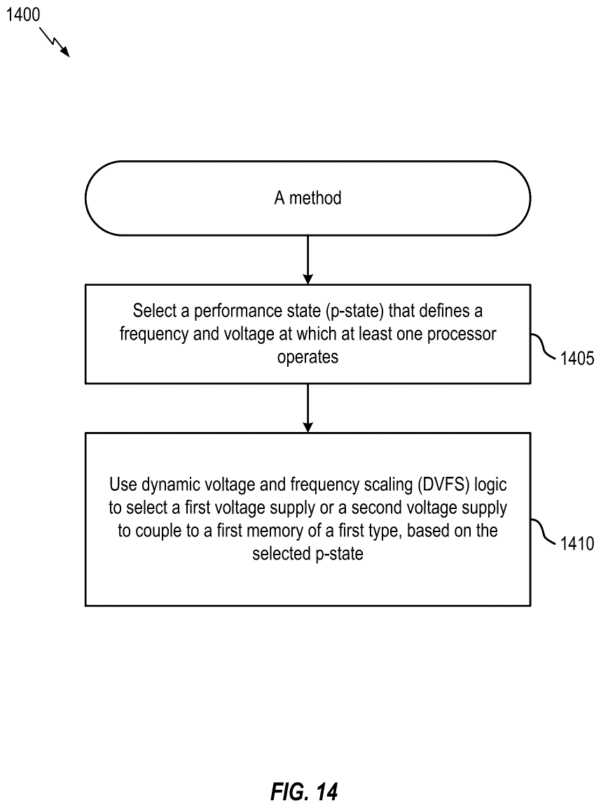

FIG. 14 shows an example of a method 1400 (e.g., performed at a wireless node). In some examples, the wireless node is a user equipment. In some examples, the wireless node is a network entity, such as a BS or a disaggregated base station.

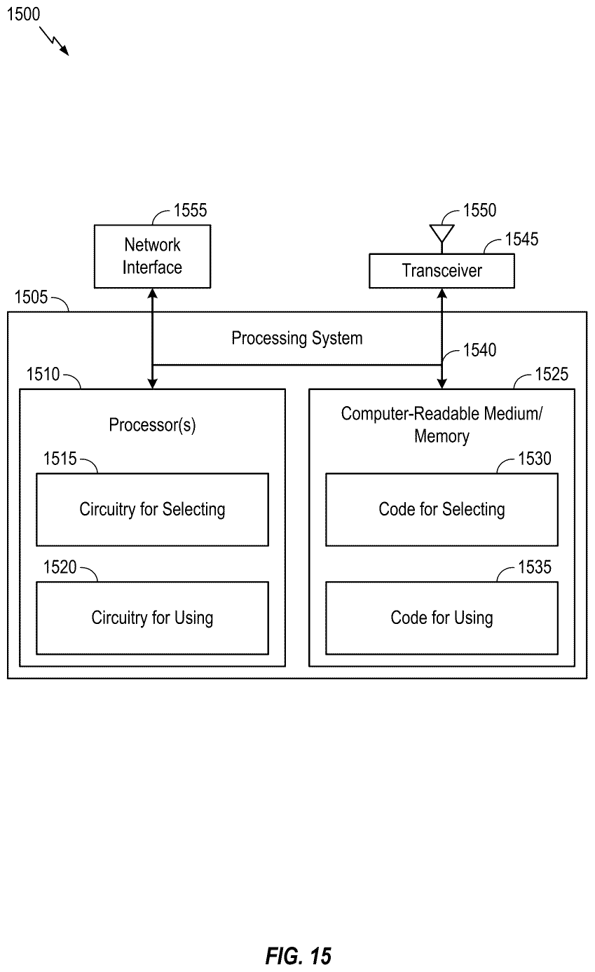

Method 1400 begins at step 1405 with selecting a performance state (p-state) that defines a frequency and voltage at which at least one processor operates. In some cases, the operations of this step refer to, or may be performed by, circuitry for selecting and/or code for selecting as described with reference to FIG. 15.

Method 1400 then proceeds to step 1410 with using dynamic voltage and frequency scaling (DVFS) logic to select a first voltage supply or a second voltage supply to couple to a first memory of a first type, based on the selected p-state. In some cases, the operations of this step refer to, or may be performed by, circuitry for using and/or code for using as described with reference to FIG. 15.

In some aspects, the DVFS logic is used to control a first multiplexor to select the first voltage supply or the second voltage supply, based on a bit value in a DVFS table entry for the selected p-state.

In some aspects, the first multiplexor comprises an adaptive power multiplexor (APM).

In some aspects, for certain p-states, the DVFS logic generates a bit signal to control a second multiplexor to bypass a voltage comparator circuit and enable the DVFS logic to control the first multiplexor.

In some aspects, different subsets of p-states are associated with different electrical margin adjust (EMA) bands.

In some aspects, the first voltage supply is coupled to a second memory of a second type, independent of the DVFS logic.

In some aspects, the first type of memory comprises high current (HC) bitcells; and the second type of memory comprises high density (HD) bitcells.

In some aspects, for a first subset of p-states, the DVFS logic selects the first voltage supply to couple to the first memory; and for a second subset of p-states, the DVFS logic selects the first voltage supply to couple to the first memory.

In some aspects, the selected p-state comprises a first p-state associated with a lower frequency and lower voltage than a second p-state; and the DVFS logic is used to switch from coupling the first voltage supply to the first memory to coupling the second voltage supply to the first memory, based on the first p-state.

In some aspects, the selected p-state comprises a first p-state associated with a higher frequency and higher voltage than a second p-state; and the DVFS logic is used to switch from coupling the second voltage supply to the first memory to coupling the first voltage supply to the first memory, based on the first p-state.

In one aspect, method 1400, or any aspect related to it, may be performed by an apparatus, such as communications device 1500 of FIG. 15, which includes various components operable, configured, or adapted to perform the method 1400. Communications device 1500 is described below in further detail.

Note that FIG. 14 is just one example of a method, and other methods including fewer, additional, or alternative steps are possible consistent with this disclosure.

### Example Communications Device(s)

FIG. 15 depicts aspects of an example communications device 1500. In some aspects, communications device 1500 is a user equipment. In some aspects, communications device 1500 is a network entity, such as a BS.

The communications device 1500 includes a processing system 1505 coupled to the transceiver 1545 (e.g., a transmitter and/or a receiver). In some aspects (e.g., when communications device 1500 is a network entity), processing system 1505 may be coupled to a network interface 1555 that is configured to obtain and send signals for the communications device 1500 via communication link(s), such as a backhaul link, midhaul link, and/or fronthaul link. The transceiver 1545 is configured to transmit and receive signals for the communications device 1500 via the antenna 1550, such as the various signals as described herein. The processing system 1505 may be configured to perform processing functions for the communications device 1500, including processing signals received and/or to be transmitted by the communications device 1500.

The processing system 1505 includes one or more processors 1510. The one or more processors 1510 are coupled to a computer-readable medium/memory 1525 via a bus 1540. In certain aspects, the computer-readable medium/memory 1525 is configured to store instructions (e.g., computer-executable code) that when executed by the one or more processors 1510, cause the one or more processors 1510 to perform the method 1400 described with respect to FIG. 14, or any aspect related to it. Note that reference to a processor performing a function of communications device 1500 may include one or more processors 1510 performing that function of communications device 1500.

In the depicted example, computer-readable medium/memory 1525 stores code (e.g., executable instructions), such as code for selecting 1530 and code for using 1535. Processing of the code for selecting 1530 and code for using 1535 may cause the communications device 1500 to perform the method 1400 described with respect to FIG. 14, or any aspect related to it.

The one or more processors 1510 include circuitry configured to implement (e.g., execute) the code stored in the computer-readable medium/memory 1525, including circuitry for selecting 1515 and circuitry for using 1520. Processing with circuitry for selecting 1515 and circuitry for using 1520 may cause the communications device 1500 to perform the method 1400 described with respect to FIG. 14, or any aspect related to it.

Various components of the communications device 1500 may provide means for performing the method 1400 described with respect to FIG. 14, or any aspect related to it. For example, means for transmitting, sending or outputting for transmission may include transceivers and/or antenna(s) such as the transceiver 1545 and the antenna 1550 of the communications device 1500 in FIG. 15. Means for receiving or obtaining may include the transceiver 1545 and the antenna 1550 of the communications device 1500 in FIG. 15.

### Example Clauses

Implementation examples are described in the following numbered clauses:

Clause 1: A method, comprising: selecting a performance state (p-state) that defines a frequency and voltage at which at least one processor operates; and using dynamic voltage and frequency scaling (DVFS) logic to select a first voltage supply or a second voltage supply to couple to a first memory of a first type, based on the selected p-state.

Clause 2: The method of Clause 1, wherein the DVFS logic is used to control a first multiplexor to select the first voltage supply or the second voltage supply, based on a bit value in a DVFS table entry for the selected p-state.

Clause 3: The method of Clause 2, wherein the first multiplexor comprises an adaptive power multiplexor (APM).

Clause 4: The method of Clause 2, wherein, for certain p-states, the DVFS logic generates a bit signal to control a second multiplexor to bypass a voltage comparator circuit and enable the DVFS logic to control the first multiplexor.

Clause 5: The method of any one of Clauses 1-4, wherein different subsets of p-states are associated with different electrical margin adjust (EMA) bands.

Clause 6: The method of any one of Clauses 1-5, wherein: the first voltage supply is coupled to a second memory of a second type, independent of the DVFS logic.

Clause 7: The method of Clause 6, wherein: the first type of memory comprises high current (HC) bitcells; and the second type of memory comprises high density (HD) bitcells.

Clause 8: The method of Clause 7, wherein: for a first subset of p-states, the DVFS logic selects the first voltage supply to couple to the first memory; and for a second subset of p-states, the DVFS logic selects the first voltage supply to couple to the first memory.

Clause 9: The method of Clause 8, wherein: the selected p-state comprises a first p-state associated with a lower frequency and lower voltage than a second p-state; and the DVFS logic is used to switch from coupling the first voltage supply to the first memory to coupling the second voltage supply to the first memory, based on the first p-state.

Clause 10: The method of Clause 8, wherein: the selected p-state comprises a first p-state associated with a higher frequency and higher voltage than a second p-state; and the DVFS logic is used to switch from coupling the second voltage supply to the first memory to coupling the first voltage supply to the first memory, based on the first p-state.

Clause 11: An apparatus, comprising: at least one memory comprising executable instructions; and at least one processor configured to execute the executable instructions and cause the apparatus to perform a method in accordance with any combination of Clauses 1-10.

Clause 12: An apparatus, comprising means for performing a method in accordance with any combination of Clauses 1-10.

Clause 13: A non-transitory computer-readable medium comprising executable instructions that, when executed by at least one processor of an apparatus, cause the apparatus to perform a method in accordance with any combination of Clauses 1-10.

Clause 14: A computer program product embodied on a computer-readable storage medium comprising code for performing a method in accordance with any combination of Clauses 1-10.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the general principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various actions may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

The various illustrative logical blocks, modules and circuits described in connection with the present disclosure may be implemented or performed with a general purpose processor, a graphics processing unit (GPU), a neural processing unit (NPU), a digital signal processor (DSP), an ASIC, a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, a system on a chip (SoC), or any other such configuration.

As used herein, “a processor,” “at least one processor” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

In some cases, rather than actually transmitting a signal, an apparatus (e.g., a wireless node or device) may have an interface to output the signal for transmission. For example, a processor may output a signal, via a bus interface, to a radio frequency (RF) front end for transmission. Accordingly, a means for outputting may include such an interface as an alternative (or in addition) to a transmitter or transceiver. Similarly, rather than actually receiving a signal, an apparatus (e.g., a wireless node or device) may have an interface to obtain a signal from another device. For example, a processor may obtain (or receive) a signal, via a bus interface, from an RF front end for reception. Accordingly, a means for obtaining may include such an interface as an alternative (or in addition) to a receiver or transceiver.

While the present disclosure may describe certain operations as being performed by one type of wireless node, the same or similar operations may also be performed by another type of wireless node. For example, operations performed by a user equipment (UE) may also (or instead) be performed by a network entity (e.g., a base station or unit of a disaggregated base station). Similarly, operations performed by a network entity may also (or instead) be performed by a UE.

Further, while the present disclosure may describe certain types of communications between different types of wireless nodes (e.g., between a network entity and a UE), the same or similar types of communications may occur between same types of wireless nodes (e.g., between network entities or between UEs, in a peer-to-peer scenario). Further, communications may occur in reverse order than described.

Means for obtaining, means for computing, and means for scheduling may comprise one or more processors, such as one or more of the processors described above with reference to FIG. 1 and/or FIG. 15.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

The methods disclosed herein comprise one or more actions for achieving the methods. The method actions may be interchanged with one another without departing from the scope of the claims. In other words, unless a specific order of actions is specified, the order and/or use of specific actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor. Software shall be construed broadly to mean instructions, instruction sets, code, code segments, program code, programs, subprograms, software modules, applications, software applications, software packages, routines, subroutines, objects, executables, threads of execution, procedures, or functions, whether referred to as software, firmware, middleware, microcode, hardware description language, or otherwise.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for”. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. A method, comprising:
selecting a performance state (p-state) that defines a frequency and voltage at which at least one processor operates; and
using dynamic voltage and frequency scaling (DVFS) logic to select a first voltage supply or a second voltage supply to couple to a first memory of a first type, based on the selected p-state.

2. The method of claim 1, wherein the DVFS logic is used to control a first multiplexor to select the first voltage supply or the second voltage supply, based on a bit value in a DVFS table entry for the selected p-state.

3. The method of claim 2, wherein the first multiplexor comprises an adaptive power multiplexor (APM).

4. The method of claim 2, wherein, for certain p-states, the DVFS logic generates a bit signal to control a second multiplexor to bypass a voltage comparator circuit and enable the DVFS logic to control the first multiplexor.

5. The method of claim 1, wherein different subsets of p-states are associated with different electrical margin adjust (EMA) bands.

6. The method of claim 1, wherein:
the first voltage supply is coupled to a second memory of a second type, independent of the DVFS logic.

7. The method of claim 6, wherein:
the first type of memory comprises high current (HC) bitcells; and
the second type of memory comprises high density (HD) bitcells.

8. The method of claim 7, wherein:
for a first subset of p-states, the DVFS logic selects the first voltage supply to couple to the first memory; and
for a second subset of p-states, the DVFS logic selects the first voltage supply to couple to the first memory.

9. The method of claim 8, wherein:
the selected p-state comprises a first p-state associated with a lower frequency and lower voltage than a second p-state; and
the DVFS logic is used to switch from coupling the first voltage supply to the first memory to coupling the second voltage supply to the first memory, based on the first p-state.

10. The method of claim 8, wherein:
the selected p-state comprises a first p-state associated with a higher frequency and higher voltage than a second p-state; and
the DVFS logic is used to switch from coupling the second voltage supply to the first memory to coupling the first voltage supply to the first memory, based on the first p-state.

11. An apparatus, comprising:
at least one memory comprising computer-executable instructions; and
one or more processors configured to execute the computer-executable instructions and cause the apparatus to:
select a performance state (p-state) that defines a frequency and voltage at which at least one processor operates; and
use dynamic voltage and frequency scaling (DVFS) logic to select a first voltage supply or a second voltage supply to couple to a first memory of a first type, based on the selected p-state.

12. The apparatus of claim 11, wherein the DVFS logic is used to control a first multiplexor to select the first voltage supply or the second voltage supply, based on a bit value in a DVFS table entry for the selected p-state.

13. The apparatus of claim 12, wherein the first multiplexor comprises an adaptive power multiplexor (APM).

14. The apparatus of claim 12, wherein, for certain p-states, the DVFS logic generates a bit signal to control a second multiplexor to bypass a voltage comparator circuit and enable the DVFS logic to control the first multiplexor.

15. The apparatus of claim 11, wherein different subsets of p-states are associated with different electrical margin adjust (EMA) bands.

16. The apparatus of claim 11, wherein:
the first voltage supply is coupled to a second memory of a second type, independent of the DVFS logic.

17. The apparatus of claim 16, wherein:
the first type of memory comprises high current (HC) bitcells; and
the second type of memory comprises high density (HD) bitcells.

18. The apparatus of claim 17, wherein:
for a first subset of p-states, the DVFS logic selects the first voltage supply to couple to the first memory; and
for a second subset of p-states, the DVFS logic selects the first voltage supply to couple to the first memory.

19. The apparatus of claim 18, wherein:
the selected p-state comprises a first p-state associated with a lower frequency and lower voltage than a second p-state; and
the DVFS logic is used to switch from coupling the first voltage supply to the first memory to coupling the second voltage supply to the first memory, based on the first p-state.

20. An apparatus, comprising:
means for selecting a performance state (p-state) that defines a frequency and voltage at which at least one processor operates; and
means for using dynamic voltage and frequency scaling (DVFS) logic to select a first voltage supply or a second voltage supply to couple to a first memory of a first type, based on the selected p-state.
